(19) United States
(12) Patent Application Publication
(10) Pub. No.: US 2026/0255508 A1
(43) Pub. Date: Aug. 27, 2026

(54) WATERPROOF DISPLAY DEVICE AND SPLICED DISPLAY APPARATUS

(71) Applicants: BEIJING BOE DISPLAY TECHNOLOGY CO., LTD., Beijing (CN); BOE TECHNOLOGY GROUP CO., LTD., Beijing (CN)

(72) Inventors: Zhaoshou TIAN, Beijing (CN); Dan LI, Beijing (CN); Qingshan QU, Beijing (CN); Haijun SHI, Beijing (CN); Bochang WANG, Beijing (CN); Hongbo FENG, Beijing (CN)

(21) Appl. No.: 18/993,810

(22) PCT Filed: Aug. 31, 2023
(86) PCT No.: PCT/CN2023/116236

§ 371 Date: Jan. 13, 2025

(51) Int. Cl. H05K 5/02; H05K 5/30

(52) U.S. Cl. CPC H05K 5/0217; H05K 5/0247; H05K 5/30

(57) ABSTRACT

At least one embodiment of the present disclosure provides a waterproof display device and a splicing display apparatus, and the waterproof display device includes: a backlight module and a display component, the backlight module includes a back plate, and the back plate includes a bottom plate; the display component includes a diffusion plate, a support structure is arranged between the bottom plate and the diffusion plate, and a pressure adjustment structure is arranged on a side of the support structure away from the diffusion plate; the support structure includes a first elastic member, the support structure is configured to elastically support the diffusion plate, and the pressure adjustment structure includes a second elastic member, and the pressure adjustment structure is configured to balance a pressure inside and outside the waterproof display device.

### TECHNICAL FIELD

Embodiments of the present disclosure relate to a waterproof display device and a spliced display apparatus.

### BACKGROUND

A spliced display apparatus is usually formed by splicing multiple independent display devices, with the change of outdoor and other application scenes, it is usually necessary for a display device to have a larger size, and in order to meet the needs of various application scenes, spliced display apparatuses are widely used. Each independent display device usually comprises a display component and a backlight component. The middle frame included in the backlight component is arranged at a side of the display component, and the middle frame is provided with a bearing platform which can bear the display component, and the bearing platform needs to be connected and fixed with the non-display area of the display component through adhesive. The back plate included in the backlight component can support the middle frame. The backlight component provides backlight for the display component, and the display component includes a display panel, a diffusion plate and a light guide plate.

### SUMMARY

At least one embodiment of the present disclosure provides a waterproof display device and a spliced display apparatus. In the waterproof display device, a support structure is arranged between a bottom plate and a diffusion plate, and a pressure adjustment structure is arranged on a side of the support structure away from the diffusion plate; the support structure comprises a first elastic member, the support structure is configured to elastically support the diffusion plate, the pressure adjustment structure comprises a second elastic member, and the pressure adjustment structure is configured to balance the pressure inside and outside the waterproof display device. When the display component comprised in the waterproof display device is subjected to the pressure exerted by the external water environment underwater or thermally expands due to its own heat dissipation, the support structure will move with the expansion and contraction of the first elastic member to stably support the diffusion plate, and at the same time, the size of the internal space of the pressure adjustment structure can be adjusted through the expansion and contraction of the second elastic member comprised in the pressure adjustment structure, so as to release the pressure inside the waterproof display device on the premise of waterproof.

At least one embodiment of the present disclosure provides a waterproof display device, the waterproof display device comprises: a backlight module and a display component, in which the backlight module comprises a back plate, and the back plate comprises a bottom plate; the display component comprises a diffusion plate, a support structure is arranged between the bottom plate and the diffusion plate, and a pressure adjustment structure is arranged on a side of the support structure away from the diffusion plate; the support structure comprises a first elastic member, the support structure is configured to elastically support the diffusion plate, and the pressure adjustment structure comprises a second elastic member, and the pressure adjustment structure is configured to balance a pressure inside and outside the waterproof display device.

For example, in the waterproof display device provided by at least one embodiment of the present disclosure, the support structure comprises a support body in contact with the diffusion plate, a first base and a second base; the first base comprises a cylindrical part connected with the support body and a first support seat parallel to the bottom plate; the second base comprises a second support seat parallel to the bottom plate, the first support seat is further away from the diffusion plate relative to the second support seat, the second support seat comprises a through hole, and the cylindrical part penetrates through the through hole to be connected with the support body; the first elastic member is annularly arranged outside the cylindrical part, a first end of the first elastic member is connected with the support body, and a second end of the first elastic member is connected with the second support seat.

For example, in the waterproof display device provided by at least one embodiment of the present disclosure, the bottom plate comprises a convex part protruding to a side away from the diffusion plate, two ends of the second support seat are lapped on two sides of the bottom plate corresponding to the convex part to form a first cavity structure, and the first support seat is in the first cavity structure.

For example, in the waterproof display device provided by at least one embodiment of the present disclosure, the pressure adjustment structure comprises a shell structure and a waterproof elastic layer arranged inside the shell structure, the waterproof elastic layer and the convex part constitute a second cavity structure, the second elastic member is arranged in the second cavity structure, a first end of the second elastic member is connected with a surface of the convex part away from the diffusion plate, and a second end of the second elastic member is connected with a surface of the waterproof elastic layer away from the diffusion plate.

For example, in the waterproof display device provided by at least one embodiment of the present disclosure, a gap is between the waterproof elastic layer and the shell structure.

For example, in the waterproof display device provided by at least one embodiment of the present disclosure, the shell structure comprises an outer shell and an inner shell, the inner shell extends in an extension direction of the second elastic member, two ends at a side of the inner shell are connected with two sides of the convex part respectively, and two ends at another side of the inner shell are connected with ends of the outer shell respectively; the outer shell is outside the inner shell, and forms a space for accommodating the waterproof elastic layer and the second elastic member with the inner shell and the convex part.

For example, in the waterproof display device provided by at least one embodiment of the present disclosure, a maximum size of a planar shape of the convex part is smaller than a maximum size of a planar shape of the second support seat.

For example, the waterproof display device provided by at least one embodiment of the present disclosure, further comprises an assembly board formed by combining a conversion board, a common board, a power board and a main board, in which the assembly board is arranged at a middle position of the back plate and close to an upper edge of the back plate.

For example, the waterproof display device provided by at least one embodiment of the present disclosure, further comprises a waterproof shell, in which a plurality of the pressure adjustment structures extend out of the waterproof shell, a heat dissipation plate is arranged between the waterproof shell and the assembly plate, and the heat dissipation plate is in direct contact with both the back plate and the waterproof shell.

For example, in the waterproof display device provided by at least one embodiment of the present disclosure, a fixing screw of the waterproof shell is arranged at an outer side of the waterproof shell, and the waterproof shell and the back plate are fixed by a hole-free connection structure.

For example, in the waterproof display device provided by at least one embodiment of the present disclosure, the hole-free connection structure comprises a cavity arranged on the back plate, a screw shaft insertable into the cavity, a screw shell and a nut which fix two sides of the screw shaft, a screw thread is arranged on a side of an end of the screw shaft away from the cavity, and a connection structure of connecting the nut and the screw thread is configured to fix the screw shaft.

For example, the waterproof display device provided by at least one embodiment of the present disclosure, further comprises a circuit board and an external wiring, in which the circuit board and the external wiring are both connected with the back plate through a quick-clip type hole-free connection structure.

For example, in the waterproof display device provided by at least one embodiment of the present disclosure, the quick-clip type hole-free connection structure comprises: a cavity arranged on the back plate, a screw shaft insertable into the cavity, and a screw shell for fixing two sides of the screw shaft, and a fixing member is arranged on a side of the end of the screw shaft away from the cavity, and a connection structure of connecting the fixing member and the screw shell is configured to fix the screw shaft.

For example, the waterproof display device provided by at least one embodiment of the present disclosure, further comprises a power line and a signal line, in which an integrated wire harness of the power line and the signal line is connected with an external device through a line outlet hole of the waterproof shell, and the line outlet hole adopts a waterproof structure.

For example, in the waterproof display device provided by at least one embodiment of the present disclosure, a nano waterproof rubber pad is arranged between the waterproof shell and the back plate.

For example, in the waterproof display device provided by at least one embodiment of the present disclosure, the nano waterproof rubber pad comprises a plurality of protrusion structures, and the waterproof shell comprises a plurality of grooves, and the protrusion structures are respectively inserted into the grooves to fixedly connect the waterproof shell with the nano waterproof rubber pad.

For example, in the waterproof display device provided by at least one embodiment of the present disclosure, a power line, a light bar line, a signal line, a split screen control line and an infrared probe line are integrated into a single wire harness, and at a position corresponding to a line outlet hole of the waterproof shell, a nano waterproof rubber ring is arranged outside the single wire harness, and the nano waterproof rubber ring and the line outlet hole are fixed by a screw.

For example, in the waterproof display device provided by at least one embodiment of the present disclosure, the nano waterproof rubber ring and a fixing screw hole of the line outlet hole are arranged outside the waterproof shell.

For example, in the waterproof display device provided by at least one embodiment of the present disclosure, a mating surface of the nano waterproof rubber ring and the waterproof shell is designed as an inclined surface, and an inclined angle of the inclined surface is in a range of 3 degrees to 5 degrees.

For example, in the waterproof display device provided by at least one embodiment of the present disclosure, the second elastic member is a memory spring and a material of the second elastic member is a memory alloy wire.

For example, the waterproof display device provided by at least one embodiment of the present disclosure, further comprises a flexible printed circuit board, in which the back plate further comprises a side plate which is integrally formed with the bottom plate, and the side plate comprises a stamping part and an injection-molded part, the stamping part comprises four bending parts, and an accommodation space formed by the stamping part and the injection-molded part is a fixing area for fixing the flexible printed circuit board.

For example, in the waterproof display device provided by at least one embodiment of the present disclosure, a platform part is between two bending parts of the stamping part close to the diffusion plate, and a light guide plate is arranged on the platform part.

For example, in the waterproof display device provided by at least one embodiment of the present disclosure, a bending inclined plane is between two bending parts of the stamping part away from the diffusion plate, and a surface of the injection-molded part combined with the bending inclined plane is provided with a bite pattern.

For example, in the waterproof display device provided by at least one embodiment of the present disclosure, the injection-molded part comprises a first part arranged in parallel with the bending inclined plane and a second part connected with the first part, the first part and the second part are connected by a thin wall, and a thickness of the thin wall is in a range of 0.05 mm to 0.2 mm.

For example, in the waterproof display device provided by at least one embodiment of the present disclosure, the display component further comprises a liquid crystal display panel, and the liquid crystal display panel and an end of the back plate are bonded by an optical fixing glue.

At least one embodiment of the present disclosure further comprises a spliced display apparatus, and the spliced display apparatus is formed by splicing a plurality of waterproof display devices mentioned above.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic cross-sectional structural diagram of a waterproof display device provided by at least one embodiment of the present disclosure;

FIG. 2A is an enlarged structural schematic diagram of a part of the waterproof display device provided by at least one embodiment of the present disclosure;

FIG. 2B is a schematic cross-sectional structural diagram of the connection between the stamping part and the injection-molded part provided by at least one embodiment of the present disclosure;

FIG. 3 is a schematic cross-sectional structural diagram of a support structure provided by at least one embodiment of the present disclosure;

FIG. 4 is a schematic cross-sectional structural diagram of a bottom plate and a support structure provided by at least one embodiment of the present disclosure;

FIG. 5 is an overall schematic cross-sectional structural diagram of a pressure adjustment structure and a support structure provided by at least one embodiment of the present disclosure;

FIG. 6 is an overall three-dimensional structural schematic diagram of a pressure adjustment structure and a support structure provided by at least one embodiment of the present disclosure;

FIG. 7 is a schematic planar structural diagram of an outer surface of a waterproof display device provided by at least one embodiment of the present disclosure;

FIG. 8 to FIG. 10 are schematic cross-sectional structural diagrams of a hole-free connection structure from a disconnected state to a connected state provided by at least one embodiment of the present disclosure;

FIG. 11 to FIG. 13 are schematic cross-sectional structural diagrams of a hole-free connection structure of a quick-clip type from a disconnected state to a connected state provided by at least one embodiment of the present disclosure;

FIG. 14 is a schematic cross-sectional structural diagram of a waterproof shell and a nano waterproof rubber pad provided by at least one embodiment of the present disclosure;

FIG. 15 is a schematic cross-sectional structural diagram of a waterproof shell and a line outlet hole provided by at least one embodiment of the present disclosure;

FIG. 16 is a schematic cross-sectional structural diagram of a fixing screw hole and a line outlet hole provided by at least one embodiment of the present disclosure; and

FIG. 17 is a schematic planar structural diagram of a spliced display apparatus provided by at least one embodiment of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “left,” “right” and the like are only used to indicate relative position relationship, and when the position of the object which is described is changed, the relative position relationship may be changed accordingly.

Unless otherwise defined, the features such as “parallel”, “vertical” and “identical” used in the embodiments of the present disclosure all comprise situations such as “parallel”, “vertical” and “identical” in a strict sense, and situations such as “substantially parallel”, “substantially vertical” and “substantially identical” that contain the cases of certain errors. For example, the above-mentioned term “substantially” means that the difference of the compared objects is within 10% or 5% of the average value of the compared objects. When the number of one component or element is not specified in the following of the embodiments of the present disclosure, it means that the component or element may be one or more, or may be understood as at least one. “At least one” means one or more, and “multiple/a plurality of” means at least two. The term “in a same layer” in the embodiments of the present disclosure refers to the relationship between multiple layers formed by the same material after the same one step (for example, one-step patterning process). The term “same layer” here does not always mean that the thickness of multiple layers is the same or the height of multiple layers in cross-sectional view is the same.

At present, large-size display products, especially large-size spliced display products, have no waterproof performance. For special underwater operations, wading operations, fountains and other application scenarios, the current large-size display products cannot meet the waterproof requirements, which not only affects the market layout of the large-size display products, but also causes the development of the current large-size display products unable to make further breakthroughs. Therefore, it is necessary to improve the current large-size display products and enhance the market competitiveness of the large-size display products.

The inventors of the present disclosure have noticed that improvements can be made in the overall structural design of the display device, the fixing methods of various components, the connection methods between various components, etc., so as to enable the display device to have high waterproof performance. For the large-size display products with sealed design, the temperature of the display product itself will rise due to the release of heat during the working process, which will lead to the problem of thermal expansion of the display product. In addition, in special underwater operations, wading operations, fountains and other application scenarios, the problem of poor display of display components due to the pressure on the display product will also occur, it can be considered to use new materials such as memory metal to solve the problems caused by thermal expansion and underwater pressure in the case where the waterproof display product is sealed. The inventors of the present disclosure also noticed that the positions where the components are fixed by screws are all the key points that need waterproofing design, and the positions of line outlet holes of various wires such as power lines and signal lines also need waterproofing design, and an integrated design of conversion boards, common boards, mainboards, power boards and various wires can also improve the waterproofing effect.

At least one embodiment of the present disclosure provides a waterproof display device, and the waterproof display device comprises: a backlight module and a display component; the backlight module comprises a back plate, and the back plate comprises a bottom plate; the display component comprises a diffusion plate, a support structure is arranged between the bottom plate and the diffusion plate, and a pressure adjustment structure is arranged on a side of the support structure away from the diffusion plate; the support structure comprises a first elastic member, the support structure is configured to elastically support the diffusion plate, and the pressure adjustment structure comprises a second elastic member, and the pressure adjustment structure is configured to balance the pressure inside and outside the waterproof display device. When the display component comprised in the waterproof display device is subjected to the pressure exerted by the external water environment underwater or thermally expands due to its own heat dissipation, the support structure will move along with the expansion and contraction of the first elastic member to stably support the diffusion plate, so as to ensure the OD value within a certain range and ensure the uniformity of the display image quality, and at the same time, the size of the internal space of the pressure adjustment structure can be adjusted through the expansion and contraction of the second elastic member comprised in the pressure adjustment structure, so as to balance the internal and external pressures of the waterproof display device, so that the waterproof display device can release the internal pressure of the waterproof display device on the premise of realizing waterproofing.

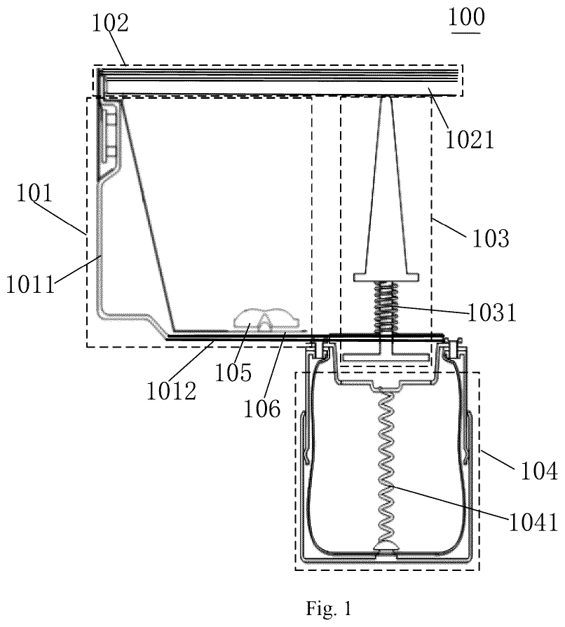

For example, FIG. 1 is a schematic cross-sectional structural diagram of a waterproof display device provided by at least one embodiment of the present disclosure. As shown in FIG. 1, the waterproof display device 100 comprises a backlight module 101 and a display component 102, the backlight module 101 comprises a back plate 1011, and the back plate 1011 comprises a bottom plate 1012; the display component 102 comprises a diffusion plate 1021, a support structure 103 is arranged between the bottom plate 1012 and the diffusion plate 1021, and a pressure adjustment structure 104 is arranged on a side of the support structure 103 away from the diffusion plate 1021; the support structure 103 comprises a first elastic member 1031, the support structure 103 is configured to elastically support the diffusion plate 1021, the pressure adjustment structure 104 comprises a second elastic member 1041, and the pressure adjustment structure 1041 is configured to balance the pressure inside and outside the waterproof display device 100. The support structure comprised in the waterproof display device will move with the expansion and contraction of the first elastic member 1031 to stably support the diffusion plate 1021, so as to ensure the OD value within a certain range and ensure the uniformity of the display image quality, at the same time, the size of the internal space of the pressure adjustment structure 104 can be adjusted by the expansion and contraction of the second elastic member 1041 comprised in the pressure adjustment structure 104, so as to balance the internal and external pressures of the waterproof display device.

For example, when the waterproof display device 100 is in operation, the display component 102 comprised in the waterproof display device 100 will radiate heat, so that the air sealed inside the waterproof display device 100 will expand due to heat, and then the diffusion plate 1021 will be subjected to an outward force exerted by the expanded air, so that the diffusion plate 1021 will slightly protrude outward. The support structure 103 will move upward with the extension of the first elastic member 1031 to stably support the diffusion plate 1021, so as to ensure that the OD value is within a certain range, thus ensuring the uniformity of the display quality of the waterproof display device 100, and at the same time, the heat inside the waterproof display device 100 is conducted to the inside of the pressure adjustment structure 1041. The second elastic member 1041 comprised in the pressure adjustment structure 104 is extended under the rising temperature, so that the internal space of the pressure adjustment structure 1041 is enlarged, and the pressure inside the waterproof display device 100 is released, so as to balance the pressure inside and outside the waterproof display device 100.

For example, when the waterproof display device 100 works underwater, the pressure exerted by the external water environment on the display component 102 increases with the increase of the diving depth of the waterproof display device 100. When the pressure is transmitted to the diffusion plate 1021, the diffusion plate 1021 collapses under the pressure to squeeze the support structure 103, and the support structure 103 will contract with the first elastic member 1031 to stably support the diffusion plate 1021. The bottom of the support structure 103 will block part of the heat from conducting to the inside of the pressure adjustment structure 1041. When the temperature around the second elastic member 1041 decreases, the second elastic member 1041 shortens, and the internal space of the pressure adjustment structure 104 shrinks, thus squeezing the sealed air inside the waterproof display device 100, and the generated internal air pressure will offset the external water pressure, so as to prevent the display component 102 from being damaged due to excessive external water pressure, and ensure that the internal pressure and the external pressure of the waterproof display device 100 are consistent, so as to ensure the waterproof performance of the waterproof display device 100.

For example, as shown in FIG. 1, a light source part 105 and a support plate 106 for bearing the light source part 105 are also provided on the bottom plate 1012, the light source part 105 may be a light emitting diode. For example, a plurality of light emitting diode arrays are disposed on the bottom plate 1012 to provide a backlight for the display component 102.

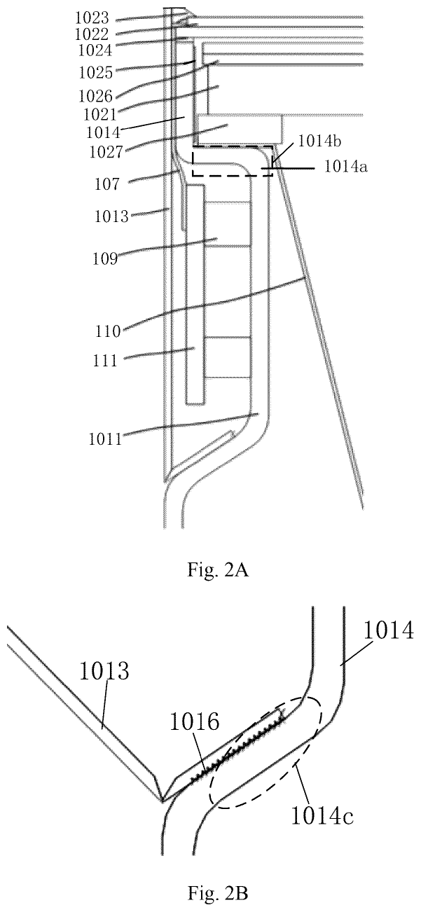

For example, FIG. 2A is an enlarged structural schematic diagram of a part of the waterproof display device provided by at least one embodiment of the present disclosure. Combining with FIG. 1 and FIG. 2A, the waterproof display device 100 comprises an appearance sealant 1023, a display panel 1022, an optical fixing glue 1024, a diffuse reflection sheet 1025, an optical film material 1026, a diffusion plate 1021, a light guide plate 1027, a flip-chip film 107, an injection-molded part 1013 of the back plate 1011, a stamping part 1014 of the back plate 1011, a support foam 109, a reflection piece 110 and a flexible printed circuit board 111.

For example, as shown in FIG. 2A, the periphery of all round of the stamping part 1014 of the back plate 1011 is formed by the deep pumping process, so that there are no seams at the four bending parts of the back plate 1011, so as to ensure that the waterproof display device 100 has no risk of water penetration.

For example, as shown in FIG. 2A, the bending parts of the back plate 1011 is processed by an automatic machine tool with a program control system to ensure the straightness and accuracy of the bending parts, so as to better support the display component 102.

For example, as shown in FIG. 2A, the appearance sealant 1023 can connect the display component 102 and the injection-molded part 1013 of the back plate 1011. The injection-molded part 1013 of the back plate 1011 can protect the structure in the accommodation space formed by the injection-molded part 1013 and the stamping part 1014 of the back plate 1011.

For example, as shown in FIG. 2A, the display panel 1022 may be a liquid crystal display panel, and the display panel 1022 is configured to display images.

For example, as shown in FIG. 2A, the optical fixing glue 1024 can connect the display panel 1022 with the top end of the stamping part 1014 of the back plate 1011, and connect the display panel 1022 with the optical film material 1026, the optical fixing glue 1024 is a transparent ultraviolet curing glue, and the ultraviolet curing glue also has a waterproof function, and the optical fixing glue 1024 can achieve waterproof function after being cured. For example, the optical film material 1026 may be a haze adjustment layer, which is not limited in the embodiments of the present disclosure.

For example, in one example, the tensile strength of the optical fixing glue 1024 is 6 times greater than that of ordinary optical glue, and the thickness of the optical fixing glue 1024 is greater than 0.3 mm, so as to ensure that the optical fixing glue 1024 has high elasticity and extensibility and ensure that the waterproof display device has enough elasticity to absorb the deformation of the display panel when it is subjected to the pressure of external water environment.

For example, as shown in FIG. 2A, a flip-chip film 107 is provided between the injection-molded part 1013 of the back plate 1011 and the stamping part 1014 of the back plate 1011, and the flip-chip film 107 fixes an integrated circuit (IC) on a corresponding circuit board.

For example, as shown in FIG. 2A, a flexible printed circuit board 111 is arranged in the accommodation space formed by the injection-molded part 1013 of the back plate 1011 and the stamping part 1014 of the back plate 1011, the flexible printed circuit board 111 is connected with the flip-chip film 107, and a support foam 109 is arranged between the flexible printed circuit board 111 and the stamping part 1014 of the back plate 1011, and the support foam 109 can stably support the flexible printed circuit board 111 when the temperature in the accommodation space formed by the injection-molded part 1013 of the back plate 1011 and the stamping part 1014 of the back plate 1011 changes.

For example, as shown in FIG. 2A, a light guide plate 1027 is further provided between the stamping part 1014 of the back plate 1011 and the diffusion plate 1021, and a reflection piece 110 is provided between the light guide plate 1027 and the stamping part 1014 of the back plate 1011, and the reflection piece 110 can reflect the light incident thereon so that more light can reach the display panel.

For example, as shown in FIG. 2A, the back plate 1011 further comprises a side plate 1015, the side plate 1015 is integral with the bottom plate 1012, the side plate 1015 comprises the stamping part 1014 and the injection-molded part 1013 mentioned above, the stamping part 1014 comprises four bending parts 1014a, the four bending parts 1014a make the stamping part 1014 have a protrusion part protruding to the side away from the injection-molded part 1013, and the protrusion part enables the above-mentioned accommodation space to be formed between the injection molding part 1013 and the stamping part 1014.

For example, as shown in FIG. 2A, a platform part 1014b is provided between two bending parts 1014a of the stamping part 1014 close to the diffusion plate 1021, and the above-mentioned light guide plate 1027 is arranged on the platform part 1014b, the platform part 1014b formed by stamping can stably support the light guide plate 1027 and other structures and can ensure a certain supporting strength.

For example, FIG. 2B is a schematic cross-sectional structural diagram of the connection between the stamping part and the injection-molded part provided by at least one embodiment of the present disclosure. As shown in combination with FIG. 2A and FIG. 2B, a bending inclined plane 1014c is between two bending parts 1014a of the stamping part 1014 away from the diffusion plate 1021, and the surface of the injection-molded part 1013 combined with the bending inclined plane 1014c is provided with a bite pattern 1016. The bite pattern 1016 can ensure that the bonding strength between the injection-molded part 1013 and the stamping part 1014 is higher, so that the waterproof performance of the waterproof display device 100 can be further improved.

For example, as shown in FIG. 2B, the injection-molded part 1013 comprises a first part 1013a arranged in parallel with the bending inclined plane 1014c and a second part 1013b connected with the first part 1013a, the first part 1013a and the second part 1013b are connected by a thin wall, and a thickness of the thin wall is in a range of 0.05 mm to 0.2 mm, for example, the thickness of the thin wall is 0.1 mm, to ensure that the bending of the injection-molded part 1013 can be achieved at the position of the thin wall.

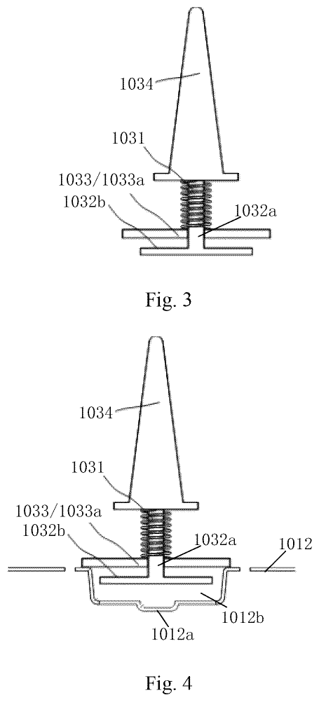

For example, FIG. 3 is a schematic cross-sectional structural diagram of a support structure provided by at least one embodiment of the present disclosure. Combining with FIG. 1 and FIG. 3, the support structure 103 comprises a support body 1034 in contact with the diffusion plate 1021, a first base 1032 and a second base 1033, the first base 1032 comprises a cylindrical part 1032a connected with the support body 1034 and a first support seat 1032b parallel to the bottom plate 1012, the second base 1033 comprises a second support seat 1033a parallel to the bottom plate 1012, the first support seat 1032b is further away from the diffusion plate 1021 than the second support seat 1033a, and the second support seat 1033a comprises a through hole, and the cylindrical part 1032a penetrates through the through hole to be connected with the support body 1034. The first elastic member 1031 is annularly arranged outside the cylindrical part 1032a, the first end of the first elastic member 1031 is connected with the support body 1034, and the second end of the first elastic member 1031 is connected with the second support seat 1033a. For example, the support body 1034 may be a nail-like structure whose size gradually increases from a position away from the diffusion plate 1021 to a position closer to the diffusion plate 1021. The first support seat 1032b and the second support seat 1033a are both plate-like structures, and the first support seat 1032b and the second support seat 1033a are parallel to each other. The first elastic member 1031 may be a freely retractable spring or the like.

For example, the support body 1034 and the first base 1032 are connected together by a mode such as secondary injection molding or snap connection, etc., and the first elastic member 1031 and the second base 1033 are located in the middle position, the cylindrical part 1032a of the first base 1032 passes through the circular hole of the second base 1033 and can move up and down under the action of the first elastic member 1031.

For example, FIG. 4 is a schematic cross-sectional structural diagram of a bottom plate and a support structure provided by at least one embodiment of the present disclosure. Combining with FIG. 1 and FIG. 4, the bottom plate 1012 includes a convex part 1012a protruding to the side away from the diffusion plate 1021, and two ends of the second support seat 1033a are lapped on two sides, corresponding to the convex part 1012a, of the bottom plate 1012 to form a first cavity structure 1012b, and the first support seat 1032b is in the first cavity structure, which can provide space for the support structure 103 to move when external pressure is applied to the diffusion plate 1021.

For example, as shown in FIG. 4, a maximum size of a planar shape of the convex part 1012a is smaller than a maximum size of a planar shape of the second support seat 1033a, so that the two ends of the second support seat 1033a can be lapped on the two sides, corresponding to the convex part 1012a, of the bottom plate 1012 to form the first cavity structure 1012b, which is convenient for the installation of the support structure 103, that is, the support structure 103 can be fixed above the convex part 1012a by the second support seat 1033a, playing a role in supporting the diffusion plate 1021.

For example, in one example, the bottom of the convex part 1012a is provided with an opening, and the minimum size of the opening is in a range of 0.5 mm to 1 mm larger than the maximum size of the first support seat 1032b, so as to ensure that when the first support seat 1032b moves to the bottom of the convex part 1012a, the temperature inside the pressure adjustment structure 104 can be effectively reduced, and ensure that when the temperature inside the waterproof display device 100 rises to a certain extent, the heat can continue to enter the pressure adjustment structure 104.

For example, the depth of the first cavity structure 1012b is consistent with the maximum movable route of the first support seat 1032b, so that the movement of the first support seat 1032b in the first cavity structure 1012b is not hindered.

For example, in one example, the second base 1033 may also be a part of the bottom plate 1012, a plurality of convex parts 1012a may be disposed on the bottom plate 1012.

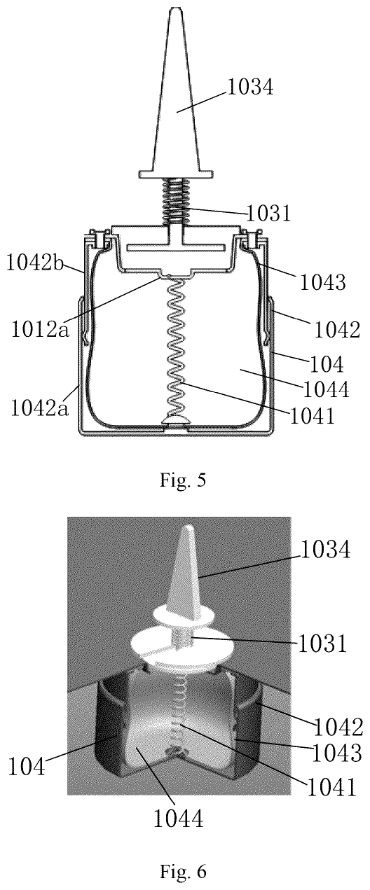

For example, FIG. 5 is an overall schematic cross-sectional structural diagram of a pressure adjustment structure and a support structure provided by at least one embodiment of the present disclosure, and FIG. 6 is an overall three-dimensional structural schematic diagram of a pressure adjustment structure and a support structure provided by at least one embodiment of the present disclosure. Combining with FIG. 1, FIG. 5 and FIG. 6, the pressure adjustment structure 104 is arranged on the other side of the convex part 1012a, and the pressure adjustment structure 104 is arranged opposite to the support structure 103, the pressure adjustment structure 104 includes a shell structure 1042 and a waterproof elastic layer 1043 arranged inside the shell structure 1042, the waterproof elastic layer 1043 and the convex part 1012a form a second cavity structure 1044 which is a sealed cavity. The second elastic member 1041 is arranged inside the second cavity structure 1044, and the first end of the second elastic member 1041 is connected to the surface of the convex part 1012a away from the diffusion plate 1021. For example, the second end of the second elastic member 1041 and the surface of the waterproof elastic layer 1043 away from the diffusion plate 1021 are connected by fixing screws. The waterproof elastic layer 1043 can not only prevent various parts from loosening which breaks the waterproof performance, that is, prevent water from entering the second cavity structure 1044, but also drive the accommodation space of the waterproof elastic layer 1043 to change under the expansion and contraction of the second elastic member 1041, so as to adjust the internal and external pressures of the second cavity structure 1044, so as to balance the external pressure and the internal pressure of the whole waterproof display device 100.

For example, as shown in FIG. 5 and FIG. 6, a gap is between the waterproof elastic layer 1043 and the shell structure 1042, and the gap provides conditions of expansion and contraction for the change of the accommodation space of the waterproof elastic layer 1043.

For example, as shown in FIG. 5 and FIG. 6, the shell structure 1042 includes an outer shell 1042a and an inner shell 1042b, and at least part of the inner shell 1042b is located within the outer shell 1042a. The inner shell 1042b extends in the extension direction of the second elastic member 1041. For example, the inner shell 1042b includes two parts that are arranged oppositely, and the inner shell 1042b extends in the vertical direction. Two ends at a side of the inner shell 1042b are connected with two sides of the convex part 1012a respectively, and two ends at another side of the inner shell 1042b are connected with ends of the outer shell 1042a respectively. For example, the two ends at another side of the inner shell 1042b and the ends of the outer shell 1042a can be connected by welding. The outer shell 1042a is located outside the inner shell 1042b, and the outer shell 1042a, the inner shell 1042b and the convex part 1012a form a space accommodating the waterproof elastic layer 1043 and the second elastic member 1041.

For example, as shown in FIG. 5 and FIG. 6, the fixing screws in the pressure adjustment structure 104 are inside the inner shell 1042b, so that the fixing screws are not in contact with the external environment, thereby further ensuring the waterproof performance of the waterproof display device 100.

For example, in one example, the bottom of the convex part 1012a is provided with a bridge structure as a position for fixing the second elastic member 1041.

For example, the second elastic member 1041 is a memory spring, and the material of the second elastic member 1041 is a memory alloy wire. The second elastic member 1041 utilizes the two-way memory effect of the shape memory alloy, and with the change of temperature, the second elastic member 1041 will actively extend or shorten without interference from other external factors.

For example, the support structure 103 cooperates with the pressure adjustment structure 104 to realize the linkage recognition of temperature and water pressure changes, automatically control the internal pressure of the waterproof display device 100, and ensure that the waterproof performance of the waterproof display device 100 is maintained in an optimal state.

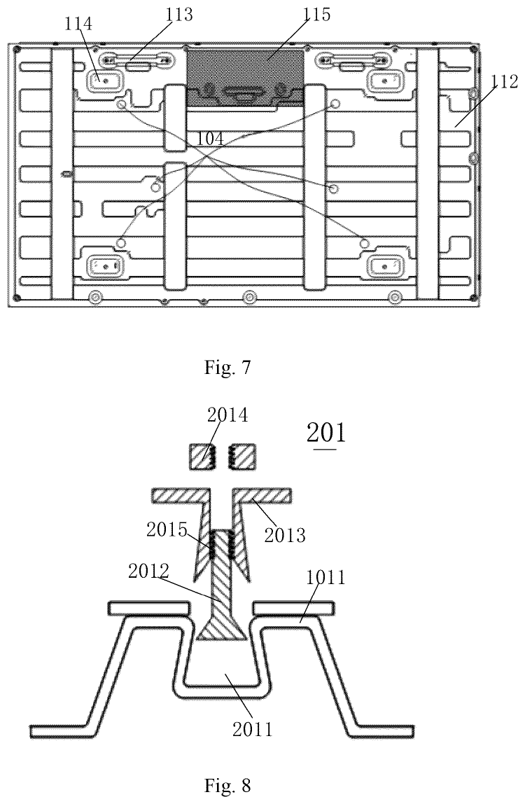

For example, FIG. 7 is a schematic planar structural diagram of an outer surface of a waterproof display device provided by at least one embodiment of the present disclosure. As shown in FIG. 7, six pressure adjustment structures 104 can be seen from the outer surface of the waterproof display device 100, and the six pressure adjustment structures 104 include three pairs of pressure adjustment structures 104, and each pair of pressure adjustment structures 104 includes two pressure adjustment structures 104 arranged oppositely.

For example, in one example, it is assumed that the volume of air enclosed in the internal environment in the waterproof display device 100 is 22.46*10⁶ mm³. According to the law of gas thermal expansion, when the pressure remains constant, the volume V of the gas changes linearly with the temperature t, that is:

$$V = V 0 ( 1 - avt ) ,$$

in which av is the volume expansion coefficient of gas at constant pressure, and the value of av of the gas is satisfied that av≈1/273.15°.

When the temperature inside the enclosed waterproof display device increases from the room temperature of 25° C. to 50° C., the volume of the gas enclosed in the internal environment increases, and it is satisfied that

$$V 1 = V 0 ( 1 + 50 / 273.15 ) - V 0 ( 1 + 25 / 273. 15 ) = 2.06 * {10}^{6} {mm}^{3} .$$

For example, in one example, the specification of the pressure adjustment structure 104 is designed as follows: the inner diameter is 80 mm and the height is 70 mm, that is, the volume inside the pressure adjustment structure is:

$$V 2 = 0.25 * {10}^{6} {mm}^{3} = π {r}^{2} = 3.14 * 40 * 40 * 70 {mm}^{3} .$$

The number of pressure adjustment structures 104 used is:

$$six = V 1 / V 2 = 2.06 * {10}^{6} / 0.25 * {10}^{6} .$$

For example, in one example, the waterproof display device 100 further includes an assembly board 115 formed by combining a conversion board, a common board, a power board and a main board. The assembly board 115 is arranged in the middle of the back plate 1011 and close to the upper edge of the back plate 1011, and is fixed on a heat dissipation board (not shown). As shown in FIG. 7, a waterproof shell 112 is arranged on the outer surface of the assembly board 115, a plurality of pressure adjustment structures 100 extend out of the waterproof shell 112, a heat dissipation plate is arranged between the waterproof shell 112 and the assembly board, and the heat dissipation plate is in direct contact with both the back plate 1011 and the waterproof shell 112, so that it is convenient to release heat in time.

For example, as shown in FIG. 7, the fixing screws for fixing the waterproof shell 112 are arranged on the outer side of the waterproof shell 112, and the waterproof shell 112 and the back plate 1011 are fixed by a hole-free connection structure, so that external water can be further prevented from entering the waterproof display device during underwater operation or wading operation, and in addition, it is convenient for later maintenance and other operations.

For example, in one example, integrated wiring harnesses such as power lines and signal lines are connected with the external device through the line outlet hole of the waterproof shell 112, and the line outlet hole also adopts a waterproof structure, to further ensure the waterproof performance of the waterproof display device.

For example, in one example, the light bar wire outlet holes are concentrated in the middle of the waterproof display device near the upper edge, so that it is convenient for the light bar wire outlet holes to be centrally fixed inside the waterproof shell 112.

For example, in one example, a flat flexible cable (FFC) enters the inner side of the back plate 1011 through the bending side edge of the back plate 1011, and then merges with the light bar wires and enters the waterproof shell 112 through the line outlet hole.

For example, FIG. 8 to FIG. 10 are schematic cross-sectional structural diagrams of a hole-free connection structure from a disconnected state to a connected state provided by at least one embodiment of the present disclosure. As shown in combination with FIG. 1 and FIG. 8 to FIG. 10, the hole-free connection structure 201 includes: a cavity 2011 which is arranged on the back plate 1011, and the cavity 2011 is a tapered cavity structure stamped from the top of the convex part 1012a in the opposite direction, a screw shaft 2012 that can be inserted into the cavity 2011, and a screw shell 2013 and a nut 2014 that fix two sides of the screw shaft 2012, and a screw thread 2015 is arranged on a side of the end of the screw shaft 2012 away from the cavity 2011. The screw shaft 2012 can be fixed by connecting the nut 2014 and the screw thread 2015, so that a hole-free connection can be realized, to reduce the risk of water entering the waterproof display device.

For example, the nut 2014 is a special hole-free connection nut, the screw shell 2013 is a special hole-free screw shell, and the screw shaft is a special hole-free screw shaft.

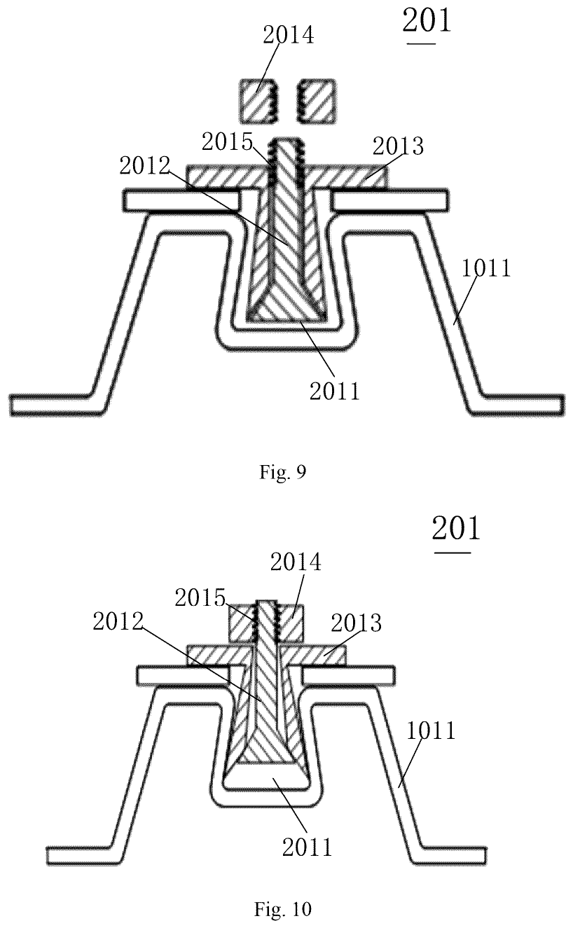

For example, in FIG. 8, the screw shaft 2012 is not inserted into the cavity 2011, the screw shell 2013 does not fix two sides of the screw shaft 2012, and the nut 2014 and the screw thread 2015 are not connected. In FIG. 9, the screw shaft 2012 is inserted into the cavity 2011, the screw shell 2013 fixes two sides of the screw shaft 2012, and the nut 2014 and the screw thread 2015 are not connected. In FIG. 10, the screw shaft 2012 is inserted into the cavity 2011, the screw shell 2013 fixes two sides of the screw shaft 2012, the screw shaft 2012 moves upward, the tapered body spreads the screw shell 2013, the screw shell 2013 is pressed against the side wall of the tapered cavity structure of the back plate 1011, and then the nut 2014 and the screw thread 2015 are connected to realize the fixation of the hole-free connection structure.

For example, in one example, the waterproof display device 100 further comprises a circuit board and an external wiring, both of the circuit board and the external wiring are connected with the back plate 1011 through a hole-free connection structure of quick-clip type, so that external water can be further prevented from entering the inside of the waterproof display device when the waterproof display device is in underwater operation or wading operation.

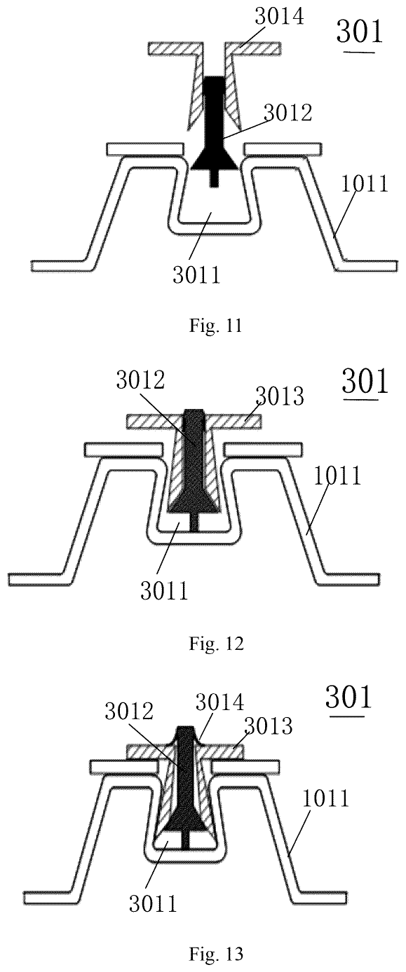

For example, FIG. 11 to FIG. 13 are schematic cross-sectional structural diagrams of a hole-free connection structure of a quick-clip type from a disconnected state to a connected state provided by at least one embodiment of the present disclosure. As shown in combination with FIG. 1 and FIG. 11 to FIG. 13, the hole-free connection structure of quick-clip type 301 includes: a cavity 3011 arranged on the back plate 1011, a screw shaft 3012 insertable into the cavity 3011, and a screw shell 3013 for fixing two sides of the screw shaft 3012. A fixing member 3014 is arranged on the side of the end of the screw shaft 3012 away from the cavity 3011, and the screw shaft 3012 can be fixed by connecting the fixing member 3014 with the screw shell 3013.

For example, the screw shell 3013 is a special hole-free screw shell, and the screw shaft 3012 is a special hole-free screw shaft.

For example, in FIG. 11, the screw shaft 3012 is not inserted into the cavity 3011, and the screw shell 3013 does not fix two sides of the screw shaft 3012. In FIG. 12, the screw shaft 3012 is inserted into the cavity 3011, the screw shell 3013 is pressed down, and the specially-made screw shaft 3012 which is in a hole-free connection mode is supported at the bottom of the cavity 3011. In FIG. 13, the top end is reversely clamped with the screw shaft 3012 to fix the screw shaft 3012, and the screw shell 3013 moves downward, the tapered body spreads the screw shell 3013, and the screw shell 3013 is pressed against the side wall of the tapered cavity structure of the back plate 1011 to fix the hole-free connection structure.

For example, as shown in FIG. 7, both the handle 113 and the connection hole 114 of the waterproof display device 100 are connected by the above-mentioned hole-free connection structure.

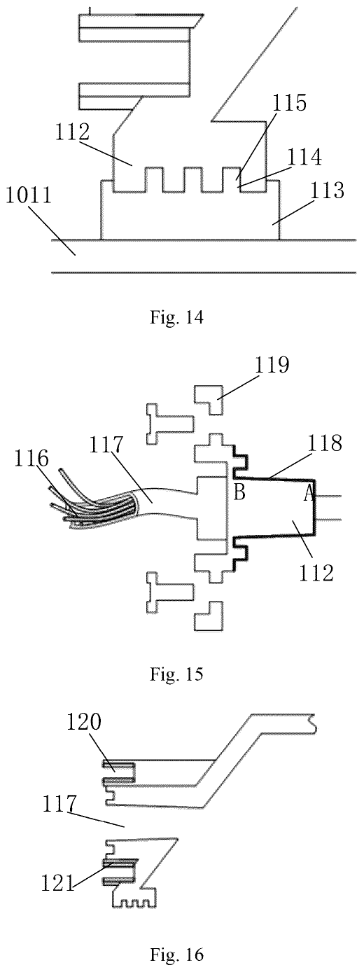

For example, FIG. 14 is a schematic cross-sectional structural diagram of a waterproof shell and a nano waterproof rubber pad provided by at least one embodiment of the present disclosure. A nano waterproof rubber pad 113 is arranged between the waterproof shell 112 and the back plate 1011, and the nano waterproof rubber pad 113 can increase the tightness to further prevent water from entering the waterproof display device 100.

For example, as shown in FIG. 14, the nano waterproof rubber pad 113 includes a plurality of protrusion structures 114, and the waterproof shell 112 includes a plurality of grooves 115, and the plurality of protrusion structures 114 are respectively inserted into the plurality of grooves 115 to fixedly connect the waterproof shell 112 with the nano waterproof rubber pad 113. It should be noted that although three grooves 115 and three protrusion structures 114 are provided in FIG. 14, the embodiments of the present disclosure are not limited to this case. In different design scenarios, other numbers of the grooves 115 and the protrusion structures 114 can also be set.

For example, FIG. 15 is a schematic cross-sectional structural diagram of a waterproof shell and a line outlet hole provided by at least one embodiment of the present disclosure. As shown in FIG. 15, the power line, a light bar line, a signal line, a split screen control line, an infrared probe line and so on may be concentrated into a single wire harness 116, and the single wire harness 116 is at the position corresponding to the line outlet hole 117 of the waterproof shell 112, and pulled out from the line outlet hole 117 of the waterproof shell 112. A nano waterproof rubber ring 118 is arranged at the outside of the single wire harness 116, and the nano waterproof rubber ring 118 and the line outlet hole 117 are fixed by screws 119 to ensure that the nano waterproof rubber ring 118 and the line outlet hole 117 can be closely matched, and the nano waterproof rubber ring 118 is arranged around the line outlet hole 117 in a whole circle to further prevent water from entering the waterproof display device.

For example, as shown in FIG. 15, the fixing screw holes of the nano waterproof rubber ring 118 and the line outlet hole 117 are arranged on the outer side of the waterproof shell 112, which can facilitate the subsequent maintenance work, and in this way, the nano waterproof rubber ring 118 can be replaced in time when the waterproof effect of the nano waterproof rubber ring 118 becomes worse.

For example, as shown in FIG. 15, the mating surface of the nano waterproof rubber ring 118 and the waterproof shell 112 is designed as an inclined surface. For example, in FIG. 15, the plane shown by AB is an inclined surface, and an inclined angle of the inclined surface with respect to the horizontal plane is in a range of 3 degrees to 5 degrees. For example, a mating surface of the waterproof shell 112 matching with the nano waterproof rubber ring 118 is also designed as the same inclined surface, and its inclined angle with respect to the horizontal plane is in a range of 3 degrees to 5 degrees, which makes that the bonding between the nano waterproof rubber ring 118 and the waterproof shell 112 becomes tighter, further improving the waterproof performance of the waterproof display device.

For example, when the screw 119 fixes the integrally formed single wire harness 116 to the waterproof shell 112, the inclined surfaces are closely matched under the squeezing force, further reducing the risk of external water infiltrating into the waterproof display device.

For example, FIG. 16 is a schematic cross-sectional structural diagram of a fixing screw hole and a line outlet hole provided by at least one embodiment of the present disclosure. As shown in combination with FIG. 15 and FIG. 16, the fixing screw hole 120 of the nano waterproof rubber ring 118 and the line outlet hole 117 is designed to be outside the waterproof shell 112, and the fixing screw hole 120 is designed as a blind hole to ensure that there is no risk of water leakage in the fixing screw hole 120.

For example, as shown in FIG. 16, a metal threaded sleeve 121 is thermally embedded in the blind hole, which can ensure the fixed strength of the blind hole and further prevent the risk of water seepage in the blind hole.

For example, the waterproof display device provided by at least one embodiment of the present disclosure maybe any product or component with a display function, such as a display, an OLED panel, an OLED TV, an electronic paper, a mobile phone, a tablet computer, a notebook computer, a digital photo frame, a navigator and so on.

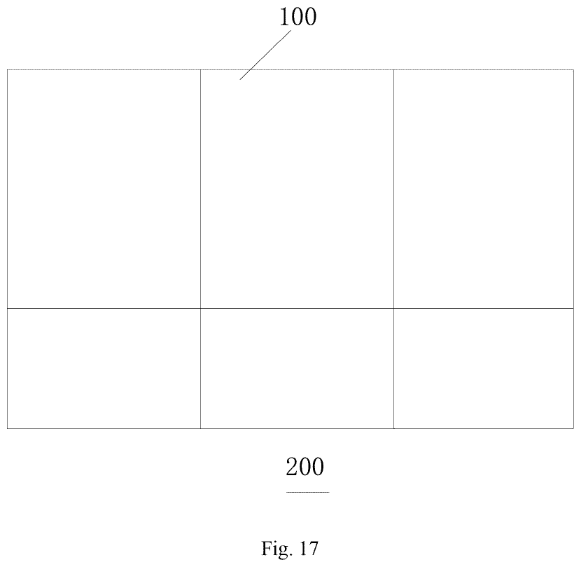

For example, at least one embodiment of the present disclosure further provides a spliced display apparatus, the spliced display apparatus is formed by splicing a plurality of waterproof display devices as described in any one of the above-mentioned embodiments. For example, FIG. 17 is a schematic planar structural diagram of a spliced display apparatus provided by at least one embodiment of the present disclosure, and as shown in FIG. 17, the spliced display apparatus 200 includes a plurality of waterproof display devices 100 provided by any one of the above embodiments. Although it is shown in FIG. 17 that the spliced display apparatus 200 includes nine waterproof display devices 100, the embodiment of the present disclosure is not limited to this case, and other numbers of waterproof display devices 100 may be included, for example, 2, 4, 6, 12 and so on.

The waterproof display device and the spliced display apparatus provided by at least one embodiment of the present disclosure have at least one of the following beneficial technical effects:
(1) By the waterproof display device provided by at least one embodiment of the present disclosure, when the display component of the waterproof display device is subjected to pressure exerted by an external water environment under water or thermally expands due to its own heat dissipation, the support structure will move with the expansion and contraction of the first elastic member to stably support the diffusion plate, so as to ensure the OD value within a certain range and ensure the uniformity of display image quality, and at the same time, the size of the internal space of the pressure adjustment structure can be adjusted through the expansion and contraction of the second elastic member included in the pressure adjustment structure, so as to balance the internal pressure and the external pressure of the waterproof display device, so that the waterproof display device can release the internal pressure of the waterproof display device on the premise of realizing waterproof.
(2) For the waterproof display device provided by at least one embodiment of the present disclosure, the bottom plate of the waterproof display device includes a convex part protruding to the side away from the diffusion plate, the two ends of the second support seat are lapped on two sides, corresponding the convex part, of the bottom plate to form a first cavity structure, and the first support seat is in the first cavity structure, so that when the external environment exerts pressure on the diffusion plate, a space for the support structure to move is existed.
(3) For the waterproof display device provided by at least one embodiment of the present disclosure, the bottom of the convex part is provided with an opening, and the minimum size of the opening is larger than the maximum size of the first support seat, so as to ensure that when the first support seat moves to the bottom of the convex part, the temperature inside the pressure adjustment structure can be effectively reduced, and the heat can continue to enter the pressure adjustment structure when the temperature inside the waterproof display device rises to a certain extent.

The following statements should be noted:
(1) The accompanying drawings involve only the structure(s) in connection with the embodiment(s) of the present disclosure, and other structure(s) can be referred to common design(s).
(2) For the sake of clarity, in the drawings used to describe embodiments of the present disclosure, the thicknesses of layers or regions are enlarged or reduced, that is, the drawings are not drawn to actual scale.
(3) In case of no conflict, the embodiments of the present disclosure and the features in the embodiments can be combined with each other to obtain new embodiments.

What have been described above are only specific implementations of the present disclosure, the protection scope of the present disclosure is not limited thereto, and the protection scope of the present disclosure should be based on the protection scope of the claims.

1. A waterproof display device, comprising: a backlight module and a display component, wherein
the backlight module comprises a back plate, and the back plate comprises a bottom plate;
the display component comprises a diffusion plate, a support structure is arranged between the bottom plate and the diffusion plate, and a pressure adjustment structure is arranged on a side of the support structure away from the diffusion plate;
the support structure comprises a first elastic member, the support structure is configured to elastically support the diffusion plate, and the pressure adjustment structure comprises a second elastic member, and the pressure adjustment structure is configured to balance a pressure inside and outside the waterproof display device.

2. The waterproof display device according to claim 1, wherein
the support structure comprises a support body in contact with the diffusion plate, a first base and a second base;
the first base comprises a cylindrical part connected with the support body and a first support seat parallel to the bottom plate;
the second base comprises a second support seat parallel to the bottom plate, the first support seat is further away from the diffusion plate relative to the second support seat, the second support seat comprises a through hole, and the cylindrical part penetrates through the through hole to be connected with the support body;
the first elastic member is annularly arranged outside the cylindrical part, a first end of the first elastic member is connected with the support body, and a second end of the first elastic member is connected with the second support seat.

3. The waterproof display device according to claim 2, wherein
the bottom plate comprises a convex part protruding to a side away from the diffusion plate, two ends of the second support seat are lapped on two sides of the bottom plate corresponding to the convex part to form a first cavity structure, and the first support seat is in the first cavity structure.

4. The waterproof display device according to claim 3, wherein
the pressure adjustment structure comprises a shell structure and a waterproof elastic layer arranged inside the shell structure, the waterproof elastic layer and the convex part constitute a second cavity structure, the second elastic member is arranged in the second cavity structure, a first end of the second elastic member is connected with a surface of the convex part away from the diffusion plate, and a second end of the second elastic member is connected with a surface of the waterproof elastic layer away from the diffusion plate.

5. The waterproof display device according to claim 4, wherein a gap is between the waterproof elastic layer and the shell structure.

6. The waterproof display device according to claim 4, wherein the shell structure comprises an outer shell and an inner shell, the inner shell extends in an extension direction of the second elastic member, two ends at a side of the inner shell are connected with two sides of the convex part respectively, and two ends at another side of the inner shell are connected with ends of the outer shell respectively; the outer shell is outside the inner shell, and forms a space for accommodating the waterproof elastic layer and the second elastic member with the inner shell and the convex part.

7. The waterproof display device according to claim 6, wherein a maximum size of a planar shape of the convex part is smaller than a maximum size of a planar shape of the second support seat.

8. The waterproof display device according to claim 6, further comprising an assembly board formed by combining a conversion board, a common board, a power board and a main board, wherein the assembly board is arranged at a middle position of the back plate and close to an upper edge of the back plate.

9. The waterproof display device according to claim 6, further comprising a waterproof shell, wherein a plurality of the pressure adjustment structures extend out of the waterproof shell, a heat dissipation plate is arranged between the waterproof shell and the assembly plate, and the heat dissipation plate is in direct contact with both the back plate and the waterproof shell.

10. The waterproof display device according to claim 9, wherein a fixing screw of the waterproof shell is arranged at an outer side of the waterproof shell, and the waterproof shell and the back plate are fixed by a hole-free connection structure.

11. The waterproof display device according to claim 10, wherein the hole-free connection structure comprises a cavity arranged on the back plate, a screw shaft insertable into the cavity, a screw shell and a nut which fix two sides of the screw shaft, a screw thread is arranged on a side of an end of the screw shaft away from the cavity, and a connection structure of connecting the nut and the screw thread is configured to fix the screw shaft.

12. The waterproof display device according to claim 9, further comprising a circuit board and an external wiring, wherein the circuit board and the external wiring are both connected with the back plate through a quick-clip type hole-free connection structure.

13. The waterproof display device according to claim 12, wherein the quick-clip type hole-free connection structure comprises: a cavity arranged on the back plate, a screw shaft insertable into the cavity, and a screw shell for fixing two sides of the screw shaft, and a fixing member is arranged on a side of the end of the screw shaft away from the cavity, and a connection structure of connecting the fixing member and the screw shell is configured to fix the screw shaft.

14. The waterproof display device according to claim 9, further comprising a power line and a signal line, wherein an integrated wire harness of the power line and the signal line is connected with an external device through a line outlet hole of the waterproof shell, and the line outlet hole adopts a waterproof structure.

15. The waterproof display device according to claim 9, wherein a nano waterproof rubber pad is arranged between the waterproof shell and the back plate.

16. The waterproof display device according to claim 15, wherein the nano waterproof rubber pad comprises a plurality of protrusion structures, and the waterproof shell comprises a plurality of grooves, and the protrusion structures are respectively inserted into the grooves to fixedly connect the waterproof shell with the nano waterproof rubber pad.

17. The waterproof display device according to claim 16, wherein a power line, a light bar line, a signal line, a split screen control line and an infrared probe line are integrated into a single wire harness, and at a position corresponding to a line outlet hole of the waterproof shell, a nano waterproof rubber ring is arranged outside the single wire harness, and the nano waterproof rubber ring and the line outlet hole are fixed by a screw.

18. The waterproof display device according to claim 17, wherein the nano waterproof rubber ring and a fixing screw hole of the line outlet hole are arranged outside the waterproof shell.

19. The waterproof display device according to claim 18, wherein a mating surface of the nano waterproof rubber ring and the waterproof shell is designed as an inclined surface, and an inclined angle of the inclined surface is in a range of 3 degrees to 5 degrees.

20. (canceled)

21. (canceled)

22. (canceled)

23. (canceled)

24. (canceled)

25. (canceled)

26. A spliced display apparatus formed by splicing a plurality of waterproof display devices according to claim 1.
